(19) United States
(12) Patent Application Publication
(10) Pub. No.: US 2019/0077975 A1
(43) Pub. Date: Mar. 14, 2019

(54) NANO-MATERIAL SHIELDING FILM AND MANUFACTURING METHOD THEREOF

(71) Applicant: APAQ TECHNOLOGY CO., LTD., MIAOLI COUNTY (TW)

(72) Inventors: CHIA-YU WU, NEW TAIPEI CITY (TW); MING-GOO CHIEN, TAICHUNG CITY (TW)

(21) Appl. No.: 15/887,944

(22) Filed: Feb. 2, 2018

(30) Foreign Application Priority Data
Sep. 13, 2017 (TW) 106131383

(51) Int. Cl. C09D 5/32; C08J 7/04; C09D 7/61; C09D 127/16; C09D 7/40; H05K 9/00

(52) U.S. Cl. CPC C09D 5/32; C08J 7/04; C09D 7/61; C08J 2367/02; C09D 7/68; C09D 7/69; H05K 9/0084; C09D 127/16

(57) ABSTRACT

A nano composite shielding film and the manufacturing method thereof for high speed signal propagation includes providing a plastic or metal substrate on which a slurry mixed by nano non-metal materials, such as nano carbon, carbon nanotube, graphene and graphite, metals, such as Fe, Ni, Mn and Zn, and polymers is coated, and curing the slurry to form the nano composite shielding film with a three-dimensional structure.

### BACKGROUND

### 1. Technical Field

The instant disclosure relates to a nano composite shielding film, and in particular, to a nano composite shielding film that can be used to shield the noise of electromagnetic interference and improve signal quality for high-speed signal transmission cables and peripheral cables.

### 2. Description of Related Art

Recently, with the improvement of technologies concerning battery electrodes, high conductivity films, and cooling components in electronics, the costs associated with graphene and carbon nanotubes have been reduced. Therefore, innovative applications of graphene and carbon nanotubes materials have been developed. In the prior art, well-known applications of graphene and carbon nanotubes include functional fabrics, sports equipment, electromagnetic shielding materials and biomedical applications. Currently, a number of electromagnetic shielding materials have been commercialized and made available on the market.

Existing shielding materials are compounds of thin film or braided metal (copper, aluminum or iron) or alloys thereof and magnetic materials such as ferrite materials (i.e., iron, manganese, zinc or nickel). However, commercial products of shielding materials in the industry are mostly of a two-dimensional structure, and the commercial products can only be used in low-frequency (less than 1 GHz) communication environments, but are unable to be used in high-speed and high-frequency signal transmission systems.

The electromagnetic interference suppressing effect of conventional shielding materials with two-dimensional structures is limited, and the shielding effect thereof when used in high-frequency environments is insufficient. Accordingly, in regard to high-speed interfaces for high-speed networks and fiber-optic communication (e.g., USB3.1, DisplayPort 1.4, HDMI 2.0 and Thunderbolt etc.), only with the use of nano-scale carbon composite materials can the noise shielding and signal matching requirements be met.

### SUMMARY

An exemplary embodiment of the present disclosure provides a method for manufacturing a nano composite shielding film, including: dissolving a predetermined proportion of carbon nanotube (CNT) and graphene (GNE) into a first N-containing organic solvent to form a first mixture; dissolving a fluorine-containing organic compound into a second N-containing organic solvent under a predetermined temperature to form a second mixture; dissolving iron-containing powder into a third N-containing organic solvent to form a third mixture; and, mixing and stirring the first mixture, the second mixture and the third mixture for a predetermined time to form a slurry. Lastly, the slurry is coated on a substrate.

Preferably, the predetermined proportion of carbon nanotube (CNT) and graphene (GNE) ranges from 1:2 to 1:10.

Preferably, the step of forming the first mixture further includes: placing the first mixture in a sealed chamber and heating the first mixture to over 100° C., so that the graphene dilates and expands, and that the carbon nanotube passes into the expanded graphene to form a three-dimensional carbon atom structure.

Preferably, the step of forming the slurry further includes: adding polyvinylpyrrolidone (PVP) as a dispersing agent into the slurry.

Preferably, after the step of coating the slurry on a substrate further includes: curing the slurry coated on a substrate to form the nano composite shielding film.

Preferably, the fluorine-containing organic compound ranges from 0.1 wt % to 10 wt % based on the weight of the slurry, and the predetermined temperature ranges from 40° C. to 50° C.

Preferably, the iron-containing powder is selected from ferrite, Fe2O3, Fe3O4, iron-cobalt-nickel alloys or combinations thereof.

Preferably, the substrate is a plastic substrate or a metal substrate.

Preferably, the nano composite shielding film has a three-dimensional carbon atom structure.

Another embodiment of the instant disclosure provides a nano composite shielding film formed on a substrate, including a mixture of a carbon nanotube, a graphene, an N-containing organic solvent, a fluorine-containing organic compound and an iron-containing powder, wherein the nano composite shielding film has a three-dimensional carbon atom structure.

To sum up, the advantages of the nano composite shielding film and the method for manufacturing the same of the instant disclosure reside in that the instant disclosure including the technical features of “dissolving a predetermined proportion of carbon nanotube (CNT) and graphene (GNE) into a first N-containing organic solvent to form a first mixture”, “dissolving a fluorine-containing organic compound into a second N-containing organic solvent under a predetermined temperature to form a second mixture”, “dissolving iron-containing powder into a third N-containing organic solvent to form a third mixture” and “mixing and stirring the first mixture, the second mixture and the third mixture for a predetermined time to form a slurry” can form a nano composite shielding film having three-dimensional carbon atom structure, which increases the shielding effect of electromagnetic interference, prevents crosstalk and signal distortion, and effectively improves signal quality.

In order to further understand the techniques, means and effects of the instant disclosure, the following detailed descriptions and appended drawings are hereby referred to, such that, and through which, the purposes, features and aspects of the instant disclosure can be thoroughly and concretely appreciated; however, the appended drawings are merely provided for reference and illustration, without any intention to be used for limiting the instant disclosure.

### BRIEF DESCRIPTION OF THE DRAWINGS

The accompanying drawings are included to provide a further understanding of the instant disclosure, and are incorporated in and constitute a part of this specification. The drawings illustrate exemplary embodiments of the instant disclosure and, together with the description, serve to explain the principles of the instant disclosure.

FIG. 1 is a flow chart of a method for manufacturing a nano composite shielding film according to an embodiment of the instant disclosure.

FIG. 2 is a schematic view of forming a nano composite shielding film provided according to an embodiment of the instant disclosure.

FIG. 3 is a structural schematic view of a nano composite shielding film provided according to an embodiment of the instant disclosure.

### DESCRIPTION OF THE EXEMPLARY EMBODIMENTS

Reference will now be made in detail to the exemplary embodiments of the instant disclosure, examples of which are illustrated in the accompanying drawings. Wherever possible, the same reference numbers are used in the drawings and the description to refer to the same or like parts.

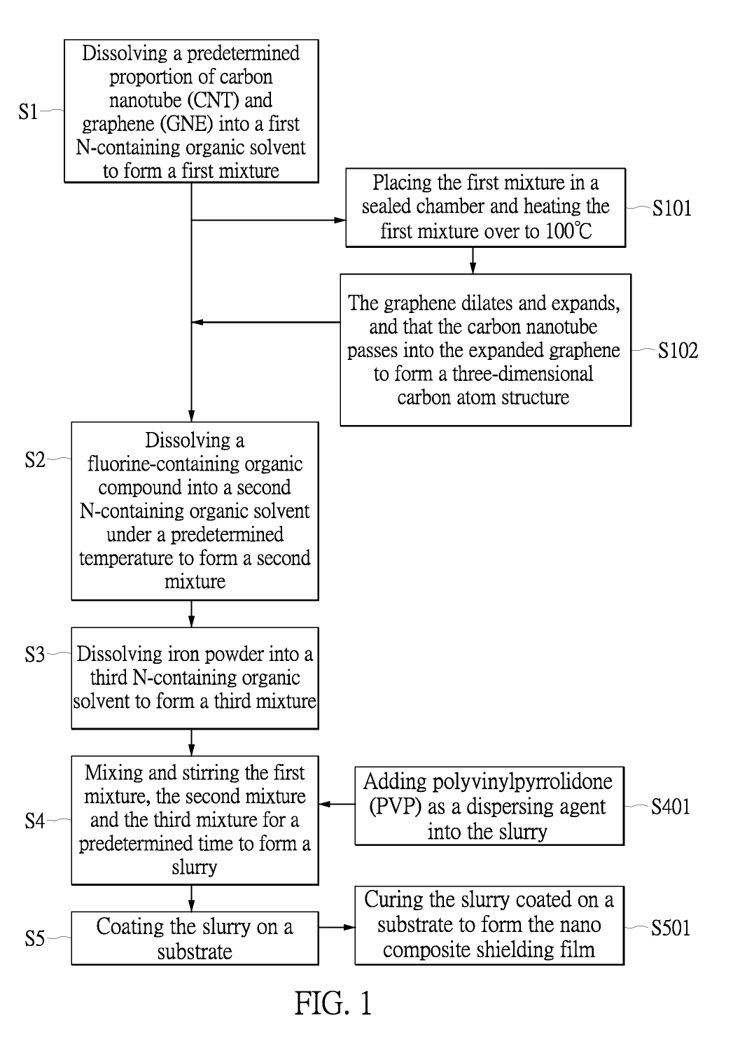

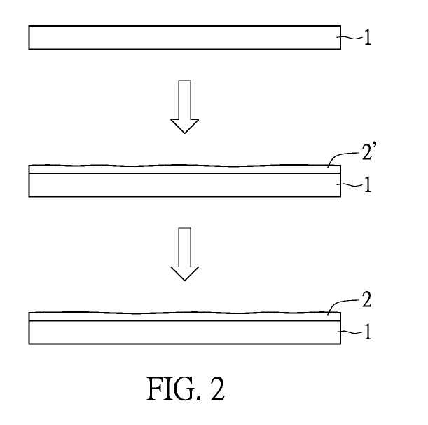

Referring to FIG. 1 and FIG. 2, an embodiment of the instant disclosure provides a nano composite shielding film 2 and a method for manufacturing the same. The method includes the following steps:

Step S1: dissolving a predetermined proportion of carbon nanotube (CNT) and graphene (GNE) into a first N-containing organic solvent to form a first mixture.

Step S2: dissolving a fluorine-containing organic compound into a second N-containing organic solvent under a predetermined temperature to form a second mixture.

Step S3: dissolving iron-containing powder into a third N-containing organic solvent to form a third mixture.

Step S4: mixing and stirring the first mixture, the second mixture and the third mixture for a predetermined time to form a slurry 2′.

Step S5: coating the slurry 2′ on a substrate 1.

Specifically, step S1, step S2 and step S3 of the method for manufacturing a nano composite shielding film in the instant disclosure are independent steps, and the order of the steps is not limited in the instant disclosure.

In the following description, the above-mentioned reference numerals for each step are used. First, step S1 is performed to mix carbon nanotubes (CNT) with graphene (GNE) in a predetermined proportion. The predetermined proportion in weight of carbon nanotubes:graphene ranges from 1:2 to 1:10, and preferably, 1:4. After the mixing step, the mixture is dissolved into a first N-containing organic solvent to form a first mixture.

Preferably, the N-containing organic solvent of the instant disclosure is 1-Methyl-2-pyrrolidone (NMP, C₅H₉NO), and is used to dissolve adhesives and disperse substances. In the instant disclosure, the major solvent is N-methylpyrrolidone.

According to the embodiment of the instant disclosure, the method further includes: adding carbon nanotube (CNT) and graphene (GNE) into a first 1-Methyl-2-pyrrolidone solvent to form a first mixture, and heating the first mixture to over 100° C. in a sealed chamber (Step S101), or preferably, heating the first mixture to over 110° C. After the heating step, the graphene of the first mixture dilates and expands, as thus, the step allows the carbon nanotube to pass into the hexagonal lattice of the expanded graphene, and form the three-dimensional carbon atom structure (Step S102).

On the other hand, step S2 is performed, including: dissolving a fluorine-containing organic compound into a second 1-Methyl-2-pyrrolidone solvent under a predetermined temperature to form a second mixture. In one embodiment, the fluorine-containing organic compound is Polyvinylidene difluoride (PVDF), which is a highly non-reactive thermoplastical fluorine-containing polymer, and is used as a dielectric material that can be electrically polarized by the predetermined temperature in the present invention. The predetermined temperature ranges from 40° C. to 50° C. Mixing the second mixture under the predetermined temperature provides the second mixture with dielectric characteristic and adhesiveness.

Furthermore, step S3 is concurrently performed, including: dissolving iron-containing powder into a third 1-Methyl-2-pyrrolidone solvent to form a third mixture. The iron-containing powder is selected from ferrite, Fe₂O₃, Fe₃O₄, iron-cobalt-nickel alloys or combinations thereof. In an embodiment, the iron-containing powder is selected from ferrite, Fe₂O₃, Fe₃O₄, iron-cobalt-nickel alloys and the combination thereof. Mixing the uniform iron-containing powder and the third 1-Methyl-2-pyrrolidone (NMP) solvent can wet the iron-containing powder.

Then, step S4 includes: mixing the first mixture, the second mixture and the third mixture which are individually obtained by step S1, step S2 and step S3, and stirring the mixture above for 4 to 6 hours to fully mix the mixture above to obtain the slurry 2′. In this step, the above wetted iron-containing powder can cover evenly on the surface of the carbon nanotube uniformly by adding the Polyvinylidene difluoride (PVDF) adhesive.

In addition, in step S401, in order to obtain a fully mixed slurry 2′, the polyvinylpyrrolidone (PVP) is added as a dispersing agent, which allows the subjects (i.e., carbon nanotube, graphene, iron-containing powder or some carbon particles) to disperse uniformly in the slurry.

Moreover, as shown in step S5, the slurry 2′ is coated on a substrate 1. The substrate 1 can be a plastic substrate or a metal substrate, said plastic being such as polyethylene terephthalate (PET). In an embodiment of the instant disclosure, the plastic substrate is a polyethylene terephthalate substrate.

Furthermore, the slurry 2′ coated on the substrate 1 may also be hardened by a curing process to form the nano composite shielding film 2 on the substrate 1 (step S501).

It should be mentioned that the Polyvinylidene difluoride (PVDF) in the embodiment of the instant disclosure based on the weight of the slurry ranges from 0.1 wt % to 10 wt %, and preferably 1 wt %.

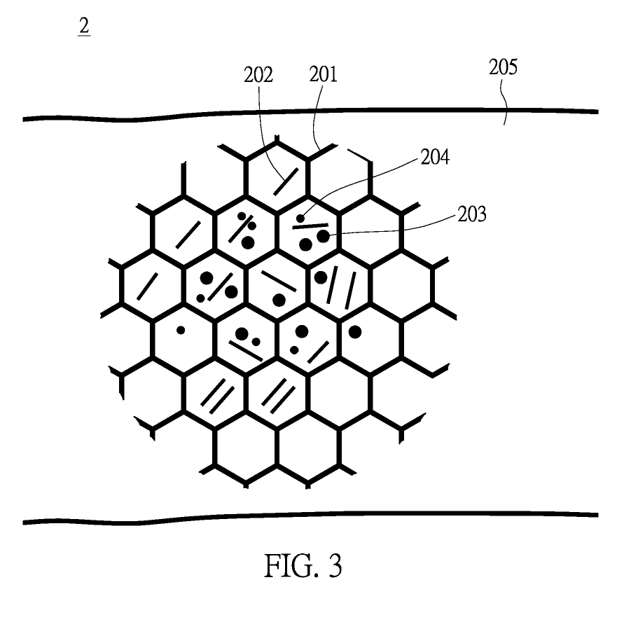

Reference is next made to FIG. 3. The nano composite shielding film 2 obtained by the previous steps includes a mixture including a graphene 201, a carbon nanotube 202, carbon particle 204, polyvinylidene fluoride (fluorine-containing organic compound) 205 and N-methylpyrrolidone (not shown in FIG. 3), and the nano composite shielding film 2 has a three-dimensional carbon atom structure.

In the embodiment of the instant disclosure, the particle size of the iron-containing powder 203 ranges from 0.1 μm to 5 μm, and the particle size of the carbon particle 204 is less than 1 μm, but it is not limited in the instant disclosure.

By virtue of the stereo carbon atom structure of the nano composite shielding film 2, the nano composite shielding film 2 can have electron orbitals that interact with each other in the vertical direction (z-direction). Thus, the nano composite shielding film 2 can have several layers of flat hexagonal structures of the graphene 201. In detail, the nano composite shielding film 2 of the present invention has 3 to 30 layers of the graphene 201, and each layer has a thickness of about 0.32 nm (3.2 Å). Overall, the nano composite shielding film 2 of the present invention can form a microscopic three-dimensional structure.

Finally, testing of the nano composite shielding film 2 of the instant disclosure is performed. The nano composite shielding film 2 effectively absorbs high-frequency electromagnetic waves (more than 1 GHz) and reflects low-frequency electromagnetic waves by the tunnel effect. In this way, the nano composite shielding film 2 of the instant disclosure can be effectively used as a shielding material for electromagnetic interference, and further be applied to the widely used 2.4 GHz and 5 GHz communication systems.

In summary, the effect of the nano composite shielding film and the method for manufacturing the same of the instant disclosure reside in that the instant disclosure including the technical features of “dissolving a predetermined proportion of carbon nanotube (CNT) and graphene (GNE) into a first N-containing organic solvent to form a first mixture”, “dissolving a fluorine-containing organic compound into a second N-containing organic solvent under a predetermined temperature to form a second mixture”, “dissolving iron-containing powder into a third N-containing organic solvent to form a third mixture” and “mixing and stirring the first mixture, the second mixture and the third mixture for a predetermined time to form a slurry” can form a nano composite shielding film with a three-dimensional carbon atom structure, which increases the shielding effect of electromagnetic interference, prevents crosstalk and signal distortion, and effectively improves signal quality

Moreover, the nano composite shielding film 2 of the instant disclosure can enhance the quality of the broadband (100 K to 10 GHz) signal and suppress noise, while at the same time having light weight, high strength and good heat conductivity.

The above-mentioned descriptions represent merely the exemplary embodiment of the present disclosure, without any intention to limit the scope of the instant disclosure thereto. Various equivalent changes, alterations or modifications based on the claims of the instant disclosure are all consequently viewed as being embraced by the scope of the instant disclosure.

What is claimed is:

1. A method for manufacturing a nano composite shielding film, comprising:
dissolving a predetermined proportion of carbon nanotube (CNT) and graphene (GNE) into a first N-containing organic solvent to form a first mixture;
dissolving a fluorine-containing organic compound into a second N-containing organic solvent under a predetermined temperature to form a second mixture;
dissolving iron-containing powder into a third N-containing organic solvent to form a third mixture;
mixing and stirring the first mixture, the second mixture and the third mixture for a predetermined time to form a slurry; and
coating the slurry on a substrate.

2. The method according to claim 1, wherein the predetermined proportion of carbon nanotube (CNT) and graphene (GNE) ranges from 1:2 to 1:10.

3. The method according to claim 1, wherein the step of forming the first mixture further includes: placing the first mixture in a sealed chamber and heating the first mixture to over 100° C., so that the graphene dilates and expands, and that the carbon nanotube passes into the expanded graphene to form a three-dimensional carbon atom structure.

4. The method according to claim 1, wherein the step of forming the slurry further includes: adding polyvinylpyrrolidone (PVP) as a dispersing agent into the slurry.

5. The method according to claim 1, wherein after the step of coating the slurry on a substrate, the method further comprises: curing the slurry coated on a substrate to form the nano composite shielding film.

6. The method according to claim 1, wherein the weight percentage of the fluorine-containing organic compound ranges from 0.1 wt % to 10 wt % based on the weight of the slurry, and the predetermined temperature ranges from 40° C. to 50° C.

7. The method according to claim 1, wherein the iron-containing powder is selected from ferrite, Fe2O3, Fe3O4, iron-cobalt-nickel alloys or combinations thereof.

8. The method according to claim 1, wherein the substrate is a plastic substrate or a metal substrate.

9. The method according to claim 5, wherein the nano composite shielding film has a three-dimensional carbon atom structure.

10. A nano composite shielding film formed on a substrate, comprising:
a mixture including a carbon nanotube, a graphene, an N-containing organic solvent, a fluorine-containing organic compound and an iron-containing powder, wherein the nano composite shielding film has a three-dimensional carbon atom structure.
